(19) United States
(12) Patent Application Publication
(10) Pub. No.: US 2026/0068697 A1
(43) Pub. Date: Mar. 5, 2026

(54) THROUGH-ASSEMBLY CONDUCTIVE VIAS OF VARYING DEPTH

(71) Applicant: Intel Corporation, Santa Clara, CA (US)

(72) Inventors: Sagar Suthram, Portland, OR (US); Doug B. Ingerly, Portland, OR (US); Wilfred Gomes, Portland, OR (US); Pushkar Sharad Ranade, San Jose, CA (US); Abhishek A. Sharma, Portland, OR (US)

(73) Assignee: Intel Corporation, Santa Clara, CA (US)

(21) Appl. No.: 18/819,008

(22) Filed: Aug. 29, 2024

(51) Int. Cl. H01L 23/538; H01L 23/00

(52) U.S. Cl. CPC H01L 23/5384

(57) ABSTRACT

Microelectronic assemblies may include through-assembly conductive vias of varying depth to couple dies or die stacks with one another via a bridge die and/or substrate. In one example, an assembly includes an interconnect structure (e.g., a bridge die) including conductive contacts on a first side and one or more integrated circuit (IC) structures bonded with a second side, where an IC structure includes one or more dies. The assembly may include a first conductive via with a first bottom end in the interconnect structure and a first top end opposite the first bottom end, and a second conductive via with a second bottom end in the interconnect structure and a second top end opposite the second bottom end, where the first top end is in a first plane and the second top end is in a second plane that is different from the first plane.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1B are cross-sectional diagrams of examples of microelectronic assemblies including through-assembly conductive vias of varying depth, in accordance with some embodiments.

FIG. 1C is a diagram of an example IC structure that may be included in an assembly including through-assembly conductive vias of varying depth, in accordance with some embodiments.

FIG. 1D is a diagram of a die that may be, or be included in, an IC structure of an assembly that includes through-assembly conductive vias of varying depth, in accordance with embodiments.

FIG. 1E is a diagram of an assembly including through-assembly conductive vias of varying depth, in accordance with embodiments.

FIG. 2 is a cross-sectional diagram of an example assembly that includes through-assembly conductive vias of varying depth, in accordance with embodiments.

FIGS. 3A-3B illustrate cross-sectional views of microelectronic assemblies including through-assembly conductive vias of varying depth, in accordance with some embodiments.

FIGS. 4A and 4B illustrate cross-sectional view of examples of IC structures that may represent bridge dies, in accordance with some examples.

FIG. 5 is a flow diagram of an example method for fabricating a microelectronic assembly with through-assembly conductive vias of varying depth, in accordance with some embodiments.

FIGS. 6-9, 10A, 10B, and 11-13 provide cross-sectional side views at various stages in the fabrication of an example assembly according to the method of FIG. 5, in accordance with some embodiments.

FIG. 14 is a top view of a wafer and dies that may include any of the IC devices disclosed herein, in accordance with any of the embodiments disclosed herein.

FIG. 15 is a side, cross-sectional view of an IC package that may include any of the IC devices disclosed herein, in accordance with various embodiments.

FIG. 16 is a side, cross-sectional view of an IC device assembly that may include any of the IC devices disclosed herein, in accordance with any of the embodiments disclosed herein.

FIG. 17 is a block diagram of an example electrical device that may include any of the IC devices disclosed herein, in accordance with any of the embodiments disclosed herein.

### DETAILED DESCRIPTION

Disclosed herein are inter-die connectivity techniques and microelectronic assemblies including through-assembly conductive vias of varying depth. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Semiconductor chip manufacturing involves a series of complex processes to create IC structures. These processes include photolithography, ion implantation, etching, and deposition. A wafer typically goes through multiple rounds of these processes to form devices and interconnects on the wafer. Once the wafer processing is complete, the wafer may be cut into individual chips (also called dies). After dicing, the individual dies are packaged to provide interconnections with other components and protection.

Packaging the dies may involve attaching the dies to a substrate (such as a motherboard, interposer, or other circuit board or structure with conductive interconnects) to connect the die's conductive contacts to the package's conductive contacts (e.g., with flip chip bonding, ball grid array (BGA), etc.). For attachment to a circuit board, a die may be soldered directly onto the board or inserted into a socket (e.g., in the case of a packaged die). In some cases, multiple dies may be combined (e.g., stacked) into a single assembly or package before being mounted on the circuit board.

Two dies or die stacks on a circuit board may communicate with one another through conductive interconnects in the circuit board and through pads and bumps at the interface between the circuit board and the dies or die stacks. Thus, conductive lines and vias in each of the dies or die stacks typically end on the bumps at the interface between the circuit board and the dies. The bumps at the interface between the dies and the circuit board can be a limiting factor with regards to performance, power delivery, and thermal management. For example, solder bumps may prevent high frequency signaling at the interface with the bumps (e.g., due to signal distortion and crosstalk). Solder bumps may also limit power delivery through an interface with solder bumps due to the limited current carrying capacity of solder bumps and the risk of electromigration in solder bumps at high current densities. Solder bumps at the interface may also pose challenges for thermal management (e.g., due to limitations in the thermal conductivity of solder bumps).

According to examples described herein, a microelectronic assembly may include through-assembly conductive vias of varying depth to couple dies or die stacks with one another via a bridge die and/or substrate. In one example, an assembly includes an interconnect structure (e.g., a bridge die) including conductive contacts on a first side and one or more integrated circuit (IC) structures bonded with a second side of the interconnect structure, where an IC structure includes one or more dies. The assembly includes a first conductive via with a first bottom end in the interconnect structure and a first top end opposite the first bottom end, and a second conductive via with a second bottom end in the interconnect structure and a second top end opposite the second bottom end, where the first top end is in a first plane and the second top end is in a second plane that is different from the first plane (e.g., the first and second conductive vias start at different planes or layers). The conductive vias may be coupled with conductive elements in the first IC structure and/or the second IC structure, which may enable a coupling the different dies or die stacks between the first and second IC structures. In some examples, the conductive vias may extend through one or more interfaces that include conductive bumps (e.g., without terminating on the bumps) to enable higher performance and/or higher density connections.

IC structures as described herein, in particular IC structures and assemblies including through-assembly conductive vias of varying depth, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures and assemblies including through-assembly conductive vias of varying depth as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

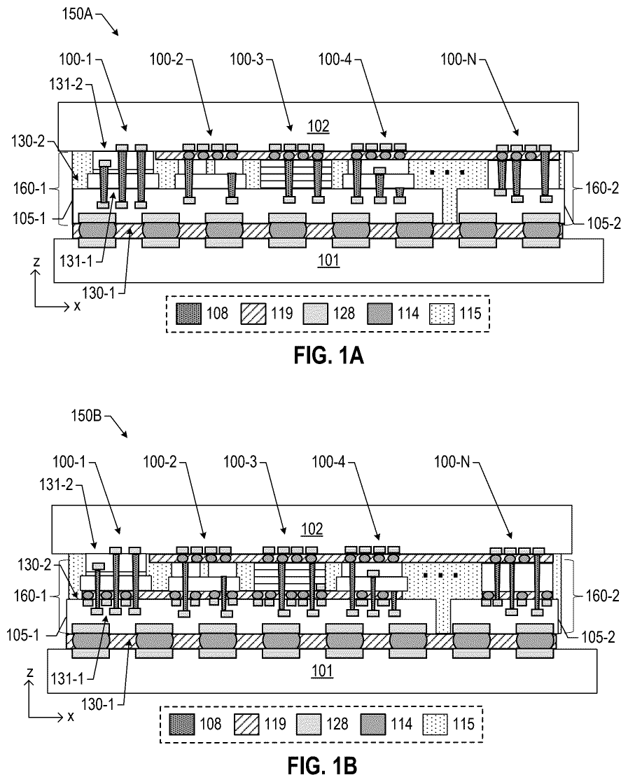

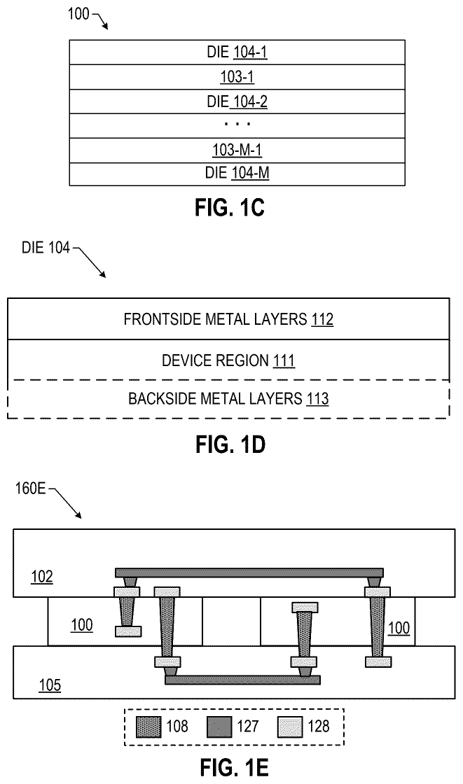

FIGS. 1A-1B are cross-sectional diagrams of examples of microelectronic assemblies 150A and 150B including a bridge die 105 and through-assembly conductive vias 108 of varying depth, in accordance with some embodiments. A number of elements referred to in the description of FIGS. 1A-1B, 1E, 2, 3A-3B, 4A-4B, 6-9, 10A-10B, and 11-13, with reference numerals are illustrated in these drawings with different patterns, with a legend showing the correspondence between the reference numerals and patterns being provided at the bottom of each drawing page containing FIGS. 1A-1B, 1E, 2, 3A-3B, 4A-4B, 6-9, 10A-10B, and 11-13. For example, the legend illustrates that FIGS. 1A-1B use different patterns to show a conductive via 108 and a conductive bump 114, and so on.

The assemblies 150A, 150B include N IC structures (of which IC structures 100-1, 100-2, 100-3, 100-4, and 100-N are shown) that are bonded with and between a substrate 102 and a bridge die (e.g., bridge dies 105-1, 105-2), where N is a positive integer greater than one. The assembly that includes the bridge dies 105-1, 105-2, the substrate 102, and the IC structures 104-1-104-N is bonded with a circuit board 101. The different IC structure 100-1-100-N are coplanar (e.g., at least some portion of each of the IC structures 100-1-100-N is in the same plane, where the plane is parallel with the substrate 102). Each of the IC structures 100-1-100-N depicted in FIGS. 1A-1B includes one or more dies. FIG. 1C illustrates an example of an IC structure 100. The IC structure 100 shown in FIG. 1C includes a plurality of M dies 104-1-104-M (of which dies 104-1, 104-2, and 104-M are shown) stacked over and bonded with one another, where M is a positive integer greater than or equal to two. An insulator material 115 may be present around and/or between adjacent IC structures 100-1-100-N.

A plurality of dies stacked over one another may be referred to as a die stack. In some examples, the number of dies 104-1-104-M in a die stack may be, e.g., two, three, four, eight, or some other positive integer greater than or equal to two. In practice, the number of dies 104-1-104-M stacked over one another in a die stack may be limited by a variety of factors, including challenges related to thermal management and connectivity. Although a stack of multiple dies 104-1-104-M is shown in FIG. 1C, in some examples, IC structures may include a single die (e.g., a single active die including logic and/or memory devices). The dies 104-1-104-M may be the same type of die, or may include different types of dies. For example, one or more of the dies 104-1-104-M may include compute logic (e.g., a processor die, an accelerator die, or other die with compute logic), a memory die, a die with both compute logic and memory devices, or another type of die. The example in FIG. 1C depicts a plurality of dies 104-1-104-M having the same dimensions (e.g., the same width, length, and thickness), however, the dies in a stack of dies may have the same or different dimensions. The IC structure 100 may include interfaces 103-1-103-M-1 (of which the interfaces 103-1 and 103-M-1 are shown) between adjacent dies of the IC structure 100 (e.g., between vertically adjacent stacked dies). The interfaces 103-1-103-M-1 may include any suitable interface (e.g., a hybrid bonding interface, an interface including conductive bumps such as BGA, or other interface).

Each one of the dies 104-1-104-M may include a device region and conductive interconnect layers. For example, FIG. 1D shows a diagram of a die 104 with a device region 111, frontside metal layers 112 over the device region, and backside metal layers 113. The device region includes devices formed over a substrate, and may include or be referred to as a front end of line (FEOL) layer. The device region 111 may include frontend devices (e.g., frontend transistors such as FinFETs, nanowire/nanoribbon transistors, frontend memory cells, or other frontend devices). The frontside metal layers 112 are over a front side of the device region, and the backside metal layers 113 are over a back side of the device region. The metal layers 112, 113 may also be referred to as back end of line (BEOL) layers. Various metal layers 112, 113 may be used to interconnect the various inputs and outputs of the devices (e.g., logic devices or memory devices) in the device regions 111. In one example, each of the metal layers may include vias and lines/trenches, as discussed in further detail below. The metal layers 112, 113 may also include devices (e.g., backend devices). Some dies may include more, fewer, and or different layers/regions than shown in FIG. 1C. For example, some dies may have only a device region and frontside metal layers 112, but lack backside metal layers. Other dies may lack a device region (e.g., an interconnect die).

Referring again to FIGS. 1A-1B, the IC structures 100-1-100-4 are disposed between the bridge die 105-1 and the substrate 102, and the IC structure 100-N is disposed between the bridge die 105-2 and the substrate 102. The IC structures 100-1-100-N may be bonded with the respective bridge dies 105-1, 105-2 and the substrate 102 in accordance with any suitable bonding technique. The examples in FIGS. 1A-1B depict a hybrid bonding interface between the IC structure 100-1 and the substrate 102, and an interface with conductive bumps 114 between the substrate 102 and the IC structures 100-2, 100-3, 100-4, and 100-N. The example in FIG. 1A depicts a hybrid bonding interface without conductive bumps between the bridge die 105-2 and the IC structure 100-N, and between the bridge die 105-1 and the IC structures 100-1, 100-2, 100-3, and 100-4. In contrast, the example in FIG. 1B depicts an interface with conductive bumps 114 between the bridge die 105-1 and the IC structures 100-1, 100-2, 100-3, and 100-4, and between the bridge die 105-2 and the IC structure 100-N. In the examples illustrated in both FIGS. 1A and 1B, the interface between the circuit board 101 and the bridge dies 105-1, 105-2 includes conductive bumps 114. Also as illustrated in the examples of FIGS. 1A-1B, the interface between the circuit board 101 and the bridge die 105 may have conductive bumps 114 with a larger pitch and width than conductive bumps at an interface between the IC structures 100-1-100-N and the bridge dies 105-1, 105-2 (when present), between the IC structures 100-1-100-N and the substrate 102 (when present), or between adjacent dies of a die stack. Other examples may include different interfaces than those depicted in FIGS. 1A-1B.

An interface with conductive bumps may include a plurality of coplanar bumps between the two bonded IC structures (e.g., between two dies of an IC structure, between an IC structure and the substrate 102, between an IC structure and one of the bridge dies 105-1, 105-2, etc.). The conductive bumps 114 are typically coupled with conductive elements, such as conductive pads 128. For example, each of the conductive bumps 114 may be between two conductive pads 128, or between a conductive pad and a conductive via 108 (not all conductive pads are illustrated in order to not clutter the drawing). In some examples, the bumps may be arranged in an array, such as in BGA assemblies. Conductive bumps may be formed to have various shapes (e.g., spherical/round, cylindrical, etc.), which may be deformed after bonding. Conductive bumps include a conductive material (e.g., one or more metals), such as solder, copper, gold, or other suitable conductive material. Conductive bumps that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of conductive bumps may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

In some examples, the conductive bumps 114 are surrounded by an insulator material 119 (sometimes referred to as a filler or underfill material) in a plane with the conductive bumps. The insulator material 119 may be provided according to any suitable method (e.g., deposited before or after formation of the bumps), and may provide mechanical support to an interface layer with conductive bumps 114. The insulator material 119 may be any suitable insulator material, such as silicon oxide, silicon carbide, silicon oxynitride, carbon-doped silicon oxide, spin-on-glass, boron-doped silicon oxide, an organic polymer, carbon, a carbon polymer, or any other suitable insulator material.

Another technique for bonding two IC structures, such as two dies, is hybrid bonding. For example, the IC structures 100-1-100-4 in FIG. 1A are hybrid bonded (e.g., without intervening conductive bumps) with the bridge die 105-1. In hybrid bonding, the bonding process is between a first layer of a first IC structure and a second layer of a second IC structure and also between conductive structures within the first layer and conductive structures within the second layer. For example, in hybrid bonding, a conductive structure (e.g., a via including metal) extends through each of the first and second layers, prior to these layers being bonded to form the bonding interface layer. For example, a first interconnect structure extends through the first layer and is exposed through, and flush with, a surface of the first layer; and a second interconnect structure extends through the second layer and is exposed through, and flush with, a surface of the second layer (e.g., prior to the bonding process). During the bonding process, surfaces of the first layer and the second layers bond to form a bonding interface layer, along with a bonding or contact of the first interconnect structure and the second interconnect structure. The interconnect structures in adjacent stacked dies that are bonded together may be, for example, conductive vias, conductive pads, or any other suitable conductive elements that may be bonded together via a hybrid bonding process. For example, some or all of the conductive vias 108 through the IC structures 100-1-100-4 in FIG. 1A may be bonded with corresponding pads 128 of the bridge die 105-1. In one example, due to unintentional practical considerations of the bonding process, the conductive interconnects of the first and second layers may not be perfectly aligned during the bonding process. Accordingly, sections of a combined interconnect structures formed through a hybrid bonding process, which extend through the bonding interface layer, may have some misalignment or offset.

Hybrid bonding may involve bonding a front side of one die to a back side of another die (e.g., “front-to-back”), bonding the back side of one die to the back side of another die (e.g., “back-to-back”), or bonding the front side of one die to the front side of another die (e.g., “front-to-front”). The side of a substrate on which a device layer is provided is typically referred to as a front side, and the other side of the substrate is referred to as a back side.

In some embodiments, hybrid bonding may be performed using insulator-insulator bonding, e.g., as oxide-oxide bonding, where an insulator material of one die is bonded with the insulator material of another die. In some embodiments, a bonding material may be present in between the faces that are bonded together. To that end, the bonding material may be applied to the one or both faces that are to be bonded and then the faces are put together, possibly while applying a suitable pressure and heating up the assembly to a suitable temperature (e.g., to moderately high temperatures, e.g., between about 50 and 200 degrees Celsius) for a duration of time. In some embodiments, the bonding material may be an adhesive material that ensures attachment of the faces of different IC structures to one another. In some embodiments, the bonding material may be an etch-stop material. In some embodiments, the bonding material may be both an etch-stop material and have suitable adhesive properties to ensure attachment of the first and second IC structures to one another. In some embodiments, the bonding material may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, could be a characteristic feature of the hybrid bonding. Using, at a bonding interface, an etch-stop material that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond.

In some embodiments, no bonding material may be used, but there will still be a bonding interface resulting from the hybrid bonding. Such a bonding interface may be recognizable as a seam or a thin layer in the microelectronic assembly, using, e.g., selective area diffraction (SED), even when the specific materials of the insulators of the layers that are bonded together may be the same, in which case the bonding interface would still be noticeable as a seam or a thin layer in what otherwise appears as a bulk insulator (e.g., bulk oxide) layer.

In some examples, one or more of the IC structures 100-1-100-N may include an interconnect die between adjacent stacked dies of the IC structure, and/or between the IC structure and the substrate 102 or bridge die 105. An interconnect die includes primarily, or exclusively, conductive interconnects, and may be thinner than a die with both a device region and interconnect layers. In some examples, an interconnect die may lack devices such as transistors. In other examples, the interconnect die may have some devices (e.g., switches) for signal routing purposes, but lack compute logic devices. In one example, an interconnect die may be hybrid bonded with dies on either side of the interconnect die.

The substrate 102 may include a structure that includes conductive interconnects, a structure that provides mechanical stability and support, or a structure that provides both conductive interconnects and mechanical support. In one example, the substrate 102 may be an interposer, interconnect die or structure, or other IC structure including conductive interconnects that are coupled with conductive interconnects in one or more of the IC structures 100-1-100-N. Conductive interconnects in the substrate 102 may include conductive traces (e.g., lines) and vias. For example, FIG. 1E illustrates an example assembly 160E in which the substrate 102 includes conductive interconnects 127 coupled with through-assembly conductive vias 108. In one such example, the substrate 102 includes primarily conductive interconnects without compute logic (e.g., compute logic may be absent from the substrate 102). In other examples, the substrate 102 may be primarily or entirely a support structure without conductive interconnects coupled with the IC structures 100-1-100-N.

In one example, the substrate 102 includes an insulating material (e.g., a dielectric material formed in multiple interconnect layers, as known in the art). In some embodiments, the insulating material of the substrate 102 may be a dielectric material, such as an organic dielectric material, a fire retardant grade 4 material (FR-4), bismaleimide triazine (BT) resin, polyimide materials, glass reinforced epoxy matrix materials, or low-k and ultra-low-k dielectric (e.g., carbon-doped dielectrics, fluorine-doped dielectrics, porous dielectrics, and organic polymeric dielectrics). The insulator material of the substrate may include any suitable interlayer dielectric (ILD) material for providing electrical isolation between portions of the substrate 102. In various embodiments, the insulator material may include materials such as silicon oxide, carbon-doped silicon oxide, silicon carbide, silicon nitride, silicon oxynitride, aluminum oxide, organic polymers such as perfluorocyclobutane or polytetrafluoroethylene, fluorosilicate glass (FSG), and organosilicates such as silsesquioxane, siloxane, or organosilicate glass. In particular, when the substrate 102 is formed using standard printed circuit board (PCB) processes, the substrate 102 may include FR-4, and the conductive pathways in the substrate 102 may be formed by patterned sheets of copper separated by buildup layers of the FR-4. In examples where the substrate 102 is formed using semiconductor fabrication processes, the insulator material of the substrate may include, e.g., one of the ILDs mentioned above.

According to some examples, the bridge dies 105-1, 105-2 are IC structures with conductive interconnects (e.g., metal lines and vias) that provide a conductive path amongst the different IC structures 100-1-100-4 and other components. For example, FIG. 1E illustrates an example in which the bridge die 105 includes conductive interconnects 127 coupled with through-assembly conductive vias 108. The bridge dies 105-1, 105-2 may also be referred to as interconnect dies, interconnect structures, or IC structures. In one example, the bridge dies 105-1, 105-2 include an insulating material (e.g., a dielectric material formed in multiple interconnect layers, as known in the art). In some examples, the bridge dies 105-1, 105-2 may include transistors configured as switches to enable configurable routing on the bridge dies 105-1, 105-2. In other examples, transistors may be absent from the bridge dies 105-1, 105-2 (e.g., the bridge dies 105-1, 105-2 may include only conductive interconnects without switching logic). The bridge dies 105-1, 105-2 include conductive contacts (e.g., the conductive pads 128, or other suitable conductive contacts) on the side facing and bonded with the circuit board, and may include further conductive contacts on the side facing and bonded with the IC structures 100-1-100-N. The bridge dies 105-1, 105-2 may accommodate different connection pitches between the IC structures 100-1-100-N and the circuit board 101. For example, the bridge dies 105-1, 105-2 may include fine-pitch conductive contacts on one side or face (e.g., the side 130-2) to match the IC structures 100-1-100-N and larger-pitch conductive contacts on the opposite side or face (e.g., the side 130-1) to match the conductive contacts on the circuit board 101. Using fanout designs and redistribution layers, the bridge dies 105-1, 105-2 can thus spread out and reroute dense chip connections to a larger area, enabling the transition from fine to coarse pitch.

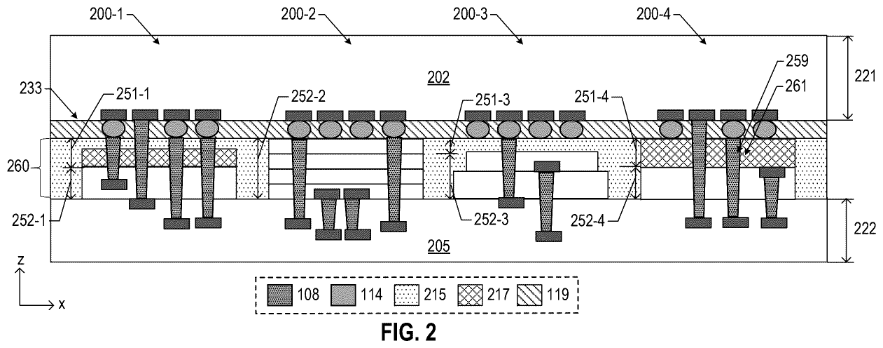

Thus, in some examples, the substrate 102 and the bridge dies 105-1, 105-2 may be similar structures in the sense that they may both include interconnect layers including conductive interconnects that are coupled with one or more of the IC structures 100-1-100-N. However, in the examples illustrated in FIGS. 1A and 1B, the bridge dies 105-1, 105-2 include larger pitch conductive contacts for attaching to the motherboard (e.g., between the circuit board 101 and the IC structures 100-1-100-N), whereas the substrate 102 may include finer pitch conductive contacts, or may lack conductive contacts. Also, in the example illustrated in FIGS. 1A and 1B, the bridge dies 105-1, 105-2 are attached to the circuit board 101, whereas the substrate 102 is bonded with the IC structures 100-1-100-N (but not attached to the circuit board 101). In one example, both the bridge dies 105-1, 105-2 and the substrate 102 may include conductive interconnects, however, the bridge dies 105-1, 105-2 may include more interconnects (e.g., more metal layers and/or more conductive interconnects in a given metal layer) than the substrate 102. In one example, regardless of the number of interconnect layers or interconnects present in the substrate 102 and the bridge die 105, the substrate may have a greater thickness (e.g., to provide more mechanical support to the assemblies 150A, 150B) than the thickness of the bridge dies 105-1, 105-2. For example, the bridge dies 105-1, 105-2 may include only or primarily metal layers, and may be thinned (which can reduce capacitance and the thickness of the resulting assemblies 150A, 150B). For example, FIG. 2, discussed below, illustrates an assembly with a bridge die 205 having a thickness 222 which is less than the thickness 221 of the substrate 202.

Referring again to FIGS. 1A and 1B, the bridge die 105, substrate 102, and IC structures 100-1-100-4 may be enclosed in a package and attached to the circuit board 101. The circuit board 101 may be a PCB, such as a motherboard, and typically includes other IC structures and/or components attached to it (not shown in FIGS. 1A-1B). The circuit board 101 may include conductive pathways and other conductive contacts (not shown) for routing power, ground, and signals through the circuit board 101 to the IC structure 100 and other IC structures attached to the circuit board 101, as known in the art. The circuit board 101 may include connectors (e.g., slots, sockets, ports, etc.) for coupling a variety of components to a computing system (e.g., processors, memory, etc.).

The assemblies 150A, 150B also include a plurality of conductive vias 108 of varying depth, which may extend through one or more dies the IC structures 100-1-100-N and which extend into one of the bridge dies 105-1, 105-2. For example, the conductive vias 108 may start in different layers/dies of the IC structures 100-1-100-N such that the lengths of different ones of the conductive vias 108 may be different. For example, the IC structure 100-1 includes two dies stacked over one another; one conductive via 108 through the IC structure 100-1 extends through one die (e.g., the bottom die closest to the bridge die 105-1) and into the bridge die 105-1, and two of the conductive vias 108 extend through two dies and into the bridge die 105-1. In another example, the IC structure 100-4 includes two dies stacked over one another; one conductive via 108 extends between a layer of the bridge die 105-1 and the side 130-1 of the bridge die 105-1 (or the side of the IC structure 100-4 facing the bridge die 105-1, as shown in FIG. 1B), a second of the conductive vias 108 is through one die of the IC structure 100-4, and a third of the conductive vias 108 is through two dies of the IC structure 100-4. The conductive vias 108 may be used for transmitting data signals, power, ground, or for providing thermal channels. In some examples, the conductive vias 108 include one or more of copper, tungsten, titanium nitride, ruthenium, molybdenum, tungsten nitride, copper aluminum, or any other suitable conductive material. In the examples illustrated in FIGS. 1A-1B, each of the conductive vias is coupled with conductive elements, such as a conductive pad 128 (which may be referred to as a bond pad, contact pad, or landing pad), a conductive bump 114, or other conductive contact or conductive element. The conductive pads 128 include a conductive material, such as one or more of copper, silver, gold, molybdenum, alloys thereof, and/or other metals.

FIGS. 1A and 1B illustrate examples of assemblies 150A, 150B in which at least some of the conductive vias 108 are formed through the IC structures 100-1-100-N after bonding one or more dies of the IC structures 100-1-100-N to the respective bridge dies 105-1, 105-2. Subassemblies including the IC structures and bridge dies (e.g., the assembly 160-1 including the bridge die 105-1 and the IC structures 100-1-100-4 and the assembly 160-2 including the bridge die 105-2 and the IC structure 100-N) may then be bonded with the substrate 102. For example, the sides or faces of the assemblies 160-1 and 160-2 that are furthest from the bridge dies 105-1, 105-2 may be bonded with the substrate 102 after forming the vias 108. The substrate 102 may provide mechanical support and/or interconnection between one or more of the vias 108.

Thus, one side or face of each of the IC structures 100-1-100-N is bonded with one of the bridge dies 105-1, 105-2, and the opposite side or face of each of the IC structures 100-1-100-N (e.g., the sides or faces of the assemblies 150A, 150B furthest from the bridge die 105) is bonded with the substrate 102. For example, the IC structure 100-1 has a first face or side 131-1 that faces and is bonded with the bridge die 105-1, and a second face or side 131-2 that faces and may be bonded with the substrate 102. Furthermore, due to first attaching the IC structures 100-1-100-N to the respective bridge dies 105-1, 105-2 and then forming conductive vias 108 through one or more dies of the IC structures 100-1-100-N, the conductive vias 108 taper in a direction from the substrate 102 towards the bridge dies 105-1, 105-2. Additionally, the conductive vias 108 of FIGS. 1A and 1B extend through the interface between the IC structures 100-1-100-N and the respective bridge dies 105-1, 105-2. Thus, the plurality of conductive vias 108 may start at various locations above the bridge dies 105-1, 105-2 (e.g., at a metal layer of one of the dies of the IC structures 100-1-100-N, at an interface between dies of an IC structure, at an interface between an IC structure and the substrate, at an interface between an IC structure and a bridge die, etc.) and end in a layer of one of the bridge dies 105-1, 105-2.

Unlike in conventional assemblies, in some examples, at least one of the conductive vias 108 may pass through an interface with conductive bumps. For example, some of the conductive vias 108 depicted in FIGS. 1A-1B extend through the interface with the substrate 102. One or more of the conductive vias 108 may also, or alternatively, extend through an interface with conductive bumps between dies of an IC structures 100-1-100-N, or through an interface between one of the bridge dies 105-1, 105-2 and one of the IC structures 100-1-100-N (e.g., as shown in FIG. 1B).

In the example illustrated in FIGS. 1A and 1B, the conductive vias 108 are formed from the side of the assemblies 160-1, 160-2 opposite the bridge dies 105-1, 105-2, and thus taper towards the bridge dies 105-1, 105-2. Various ones of the conductive vias 108 land or terminate on conductive elements in the bridge die 105 or at an interface between the IC structures 100-1-100-N and the bridge dies 105-1, 105-2. In the example illustrated in FIGS. 1A and 1B, some of the conductive vias 108 pass entirely through the IC structures 100-1-100-N (e.g., entirely through the die or die stacks of the IC structures 100-1-100-N) so that portions of the conductive vias 108 are coplanar with top layers of the IC structures 100-1-100-N through which they extend, and may also be coplanar with bottom layers of the IC structures 100-1-100-N. Other vias may extend partially through the IC structures 100-1-100-N (e.g., through fewer than all the dies of a die stack). Other conductive vias 108 may extend between the IC structures 100-1-100-N and a layer of one of the bridge dies 105-1, 105-2.

Various IC structures 100-1-100-N may include different numbers of dies (e.g., the IC structures 100-1-100-4 may include one die or multiple stacked dies) and/or different types of dies (e.g., some of the IC structures 100-1-100-4 may include only memory dies, only logic dies, dies with both logic and memory, or a combination of types of dies). The various IC structures 100-1-100-N may also have different heights or thicknesses relative to one another after bonding to one of the bridge dies 105-1, 105-2.

FIG. 2 is a cross-sectional view of an example of an assembly including through-assembly conductive vias of varying depth, which further includes IC structures 200-1-200-4 between a bridge die 205 and a substrate 202, where the IC structures 200-1-200-4 have different heights. For example, the IC structure 200-1 has a height 252-1, the IC structure 200-2 has a height 252-2, the IC structure 200-3 has a height 252-3, and the IC structure 200-4 has a height 252-4 (where the heights of the IC structures are dimensions of the IC structures in a plane substantially orthogonal to the substrate 202, e.g., along the z-axis as shown in FIG. 2). The heights of the IC structures may also be referred to as thicknesses of the IC structures.

As can be seen in FIG. 2, the height 252-2 is greater than the heights 252-1, 252-3, and 252-4. Put another way, the height or thickness of some of the IC structures is smaller than the height or thickness of other IC structures. For example, the height 252-1 and the height 252-4 are smaller than the heights 252-2 and 252-3 and the height 252-3 is smaller than the height 252-2. Thus, there is a height or thickness difference amongst the IC structures 200-1, 200-2, and 200-4 and the IC structure 200-3. Specifically, there is a thickness difference 251-1 between the IC structures 200-1 and 200-2, a thickness difference 251-3 between the IC structures 200-2 and 200-3, and a thickness difference 251-4 between the IC structures 200-4 and 200-2. In some examples, an insulator material 215 may be provided over and between adjacent ones of the IC structures 200-1-200-4 to form a substantially flat or level surface over the plurality of IC structures 200-1-200-4. The IC structure 200-3 is an example of where an insulator material 215 is over the IC structure 200-3 in a plane with a taller IC structure (e.g., the insulator material 215 over the IC structure 200-3 is coplanar with the top layer or face of the IC structure 200-2). The insulator material 215 may be the same as, or different from, the insulator material 119 in interface layers with conductive bumps 114. In some examples, the insulator material 215 may include silicon oxide, silicon carbide, silicon nitride, an organic insulator material. In other examples, a dummy die 217 may be provided over one or more of the shorter IC structures to increase the height or thickness of the structure. The IC structure 200-4 is an example where a dummy die 217 is bonded over the IC structure 200-4, where the dummy die is in a plane with the taller IC structure 200-2 (e.g., the dummy die 217 is coplanar with the top layer or face of the IC structure 200-2). A dummy die may be a die that lacks devices (e.g., active devices) and/or which lacks connectivity to active devices and/or power. In other examples, both a dummy die (or multiple dummy dies) and an insulator material 215 may be used to level the height or thickness of different IC structures 200-1-200-4 over the bridge die 205. The IC structure 200-1 is an example where both a dummy die 217 and the insulator material 215 is used to account for the height differences between IC structures over the bridge die 205.

In the example illustrated in FIG. 2, the insulator material 215 and/or dummy dies 217 are between the IC structures 200-1-200-4 and the substrate 202. In one such example, the insulator material 215 and/or dummy dies 217 are provided over the IC structures 200-1-200-4 after bonding the IC structures 200-1-200-4 to the bridge die 205 and before forming the conductive vias 108. Therefore, some of the conductive vias 108 in FIG. 2 also extend through the insulator material 215 or through a dummy die 217. For example, a portion of a conductive via 108 that extends through the IC structure 200-1 and through the insulator material 215 over the IC structure 200-1 is in a plane with a portion of the insulator material 215 between the IC structure 200-1 and the substrate 202 (e.g., between the IC structure 200-1 and the substrate 202), where the plane is parallel to the bridge die 205. Also, as shown in the example in FIG. 2, some of the conductive vias 108 extend through the dummy dies 217. In the example illustrated in FIG. 2, the conductive vias 108 through the IC structures 200-4 and 200-1 extend through a dummy die 217. For example, a portion 259 of a conductive via 108 that extends through the IC structure 100-4 and through the dummy die 217 over the IC structure 200-4 is in a plane with a portion 261 of the dummy die 217 between the IC structure 200-4 and the substrate 202 (e.g., between the IC structure 200-4 and the substrate 202), where the plane is parallel to the bridge die 205. In the example illustrated in FIG. 2, the conductive vias 108 through the IC structures 100-1, 100-3, and 100-4 start at or proximate to the insulator material 215 or dummy die 217, and therefore the widest portion of those vias may be in a plane with the insulator material 215 or a dummy die 217 (e.g., a width of a portion via 108 of FIG. 2 in a plane with the insulator material 215 or a dummy die 217 through which the via 108 extends may be wider than a portion of the via closest to the bridge die 205). In some examples where a dummy die 217 and/or an insulator material 215 is present over the IC structure, the dummy die 217 or insulator material 215 may be at, or in contact with, an interface 233 with the substrate 102. In one such example, the dummy die 217 or insulator material 215 may be in direct contact (e.g., without an intervening layer) with the interface 233. In cases where an interface layer is substantially absent between the substrate 202 and the assembly 260, a dummy die 217 and/or the insulator material 215 may be in direct contact with the substrate 202 at the interface 233.

Thus, conductive vias 108 may be formed during assembly to enable the formation of vias that extend through inter-die interfaces and into a bridge die. Conductive vias in accordance with examples described herein may enable improved system performance (e.g., by enabling high frequency signaling between adjacent IC structures on a circuit board). Conductive vias in accordance with examples described herein may also enable improved thermal management. Unlike conventional IC structures in which conductive vias terminate at interfaces with conductive bumps, resulting in thermal boundaries that limit heat dissipation, conductive vias for 3D integration can enable a thermal channel between multiple dies without thermal boundaries for improved thermal management. Finally, conductive vias formed during or after assembly of various components can enable flexibility in terms of multi-fabrication processing. For example, conductive vias may be formed at different stages of fabrication and assembly to enable the use of packages and dies from multiple fabs.

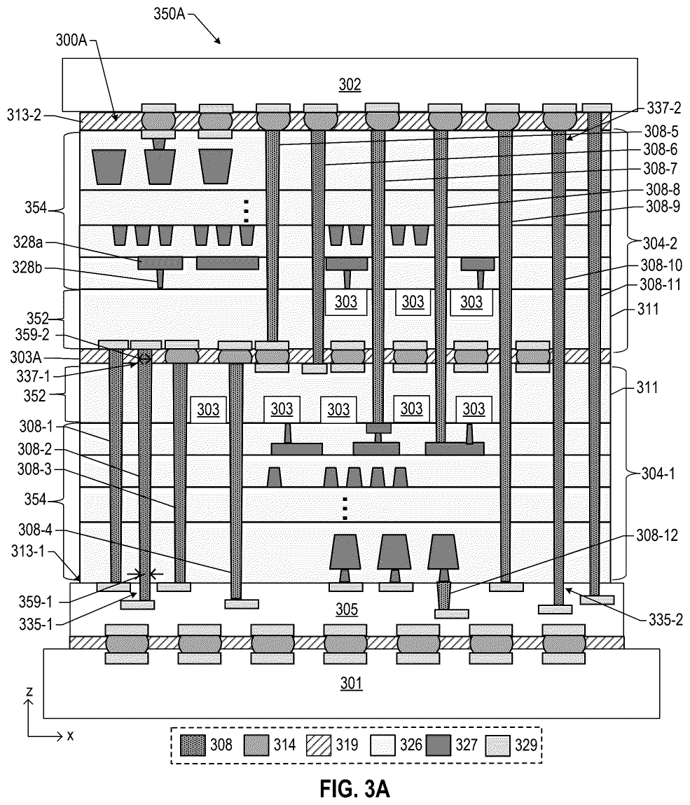

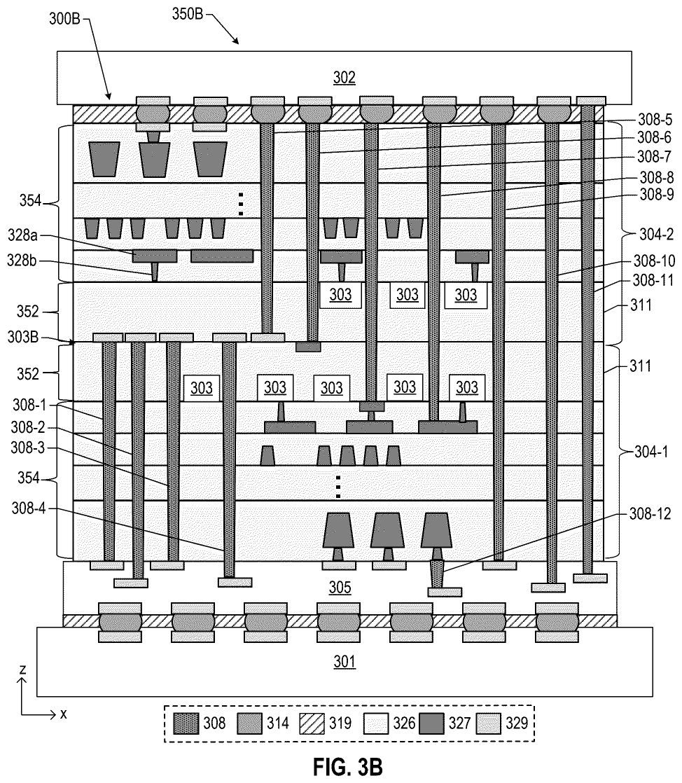

FIGS. 3A-3B illustrate cross-sectional views of an assemblies 350A, 350B including through-assembly conductive vias of varying depth. In the examples illustrated in FIGS. 3A-3B, the assemblies 350A, 350B include IC structures 300A, 300B, respectively. The IC structures 300A, 300B each include two stacked dies 304-1, 304-2 between a bridge die 305 and a substrate 302. The first die 304-1 and the second die 304-2 each include FEOL layers 352 and BEOL layers 354. The FEOL layers 352 include a device region 311, and may also include a substrate over which the device region 311 is disposed. The device region 311 includes devices (of which devices 303 are shown). The substrate may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups Ill and V of the periodic system of elements), group II-VI (i.e., materials from groups II and IV of the periodic system of elements), or group IV materials (i.e., materials from group IV of the periodic system of elements). In some embodiments, the substrate may be non-crystalline.

The device 303 is an example of a frontend device. The device 303 may be considered a “frontend device” due to its location in a FEOL layer. According to examples, the device 303 may include a transistor of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Devices in the device region 311 may be electrically isolated from one another by any suitable insulator material (e.g., any suitable ILD material 326).

The BEOL layers 354 may include a plurality of conductive interconnects 327 electrically coupled to (e.g., in electrically conductive contact with at least portions of) one or more of the plurality of devices of the FEOL layers 352. Various BEOL interconnect layers 354 may be/include one or more metal layers of a metallization stack of the dies 304-1 or 304-2. In the example illustrated in FIGS. 3A-3B, the interconnect layers 354 are disposed over a front side of the device region, and therefore may be considered frontside interconnect layers. In other examples, one or both of the dies 304-1 and 304-2 may include both frontside and backside interconnect layers. The die 304-1 may also include one or more backend devices (not shown). A device may be considered a “backend device” due to its location in a BEOL layer. A backend device may be present in lower or higher up interconnect layers in the metallization stack. In one example, a backend device may include a transistor of any architecture, such as any non-planar or planar architecture, or other device.

Various metal layers of the BEOL interconnect layers 354 may be used to interconnect the various inputs and outputs of the devices (e.g., logic devices) in the FEOL layers 352. In one example, each of the BEOL interconnect layers 354 may include vias and lines/trenches. For example, the BEOL interconnect layers 354 include via portions 328b and line or trench/interconnect portions 328a. The trench portion 328a of a metal layer is configured for transferring signals and power along electrically conductive (e.g., metal) lines (also sometimes referred to as “trenches”) extending in the x-y plane (e.g., in the x or y directions), while the via portion 328b of a metal layer is configured for transferring signals and power through electrically conductive vias extending in the z-direction, e.g., to any of the adjacent metal layers above or below. Accordingly, in one example, vias connect metal structures (e.g., metal lines or vias) from one metal layer to metal structures of an adjacent metal layer. While referred to as “metal” layers, various layers of the BEOL interconnect layers 354 may include only certain patterns of conductive metals, e.g., copper (Cu), aluminum (Al), tungsten (W), or cobalt (Co), or metal alloys, or more generally, patterns of an electrically conductive material, formed in an insulating medium such as an ILD material 326. The insulating medium may include any suitable ILD materials such as silicon oxide, carbon-doped silicon oxide, silicon carbide, silicon nitride, aluminum oxide, and/or silicon oxynitride. In some embodiments, the dielectric material 326 disposed between the interconnect structures in different ones of the interconnect layers and disposed in the device region 311 may have different compositions; in other embodiments, the composition of the dielectric material 326 between different interconnect layers and/or in the device region 311 may be the same. The examples illustrated in FIGS. 3A-3B depict three interconnect layers in the BEOL layers 354; however, fewer or more interconnect layers may be present.

As mentioned briefly above, the IC structures 300A, 300B include two dies stacked over one another (e.g., a first die 304-1 and a second die 304-2). The second die 304-2 is stacked over and bonded with the first die 304-1. FIG. 3A illustrates an example in which an interface 303A (e.g., interface layer) with conductive bumps 314 is present between the two dies 304-1, 304-2. An insulator material 319 may also be present between the dies 304-1, 304-2 in the interface 303A. FIG. 3B illustrates an example in which the dies 304-1, 304-2 are hybrid bonded, which may result in a hybrid bonding interface 303B between the first die 304-1, 304-2. Although FIGS. 3A-3B depict the second die 304-2 as having the same width as the first die 304-1 (e.g., the same dimension along the x-axis as shown in FIGS. 3A-3B), the second die 304-2 may have a width that is different from the first die 304-1 (e.g., such as the example IC structures 100-1 and 100-4 of FIGS. 1A and 1B). In some examples, one or multiple smaller coplanar dies may be bonded over the first die 304-1 (e.g., such as the example IC structure 100-2 of FIGS. 1A and 1B).

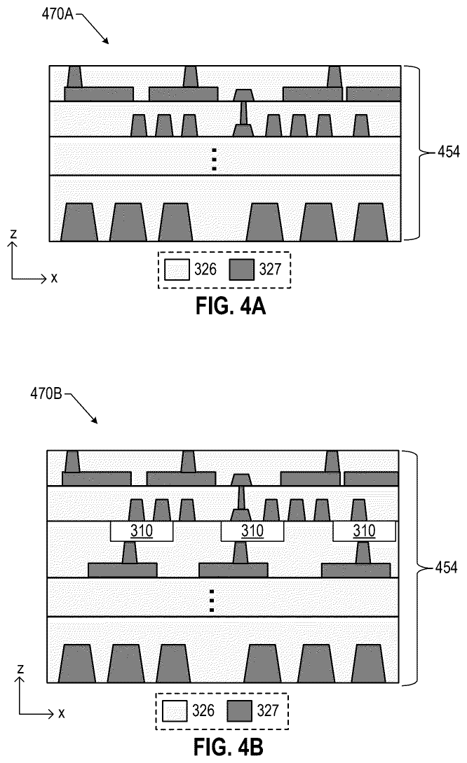

The die stack that includes the dies 304-1 and 304-2 is over and bonded with the bridge die 305 via an interface 313-1, and a substrate 302 is over and bonded with the die stack via an interface 313-2. The bridge die 305 may be an example of the bridge die 105, and the substrate 302 may be an example of the substrate 102, discussed above. The substrate 302 and/or the bridge die 305 may include a plurality of interconnect layers that include conductive interconnects. In some examples, the bridge die 305 may include transistors (e.g., transistors configured as switches to enable configurable routing of signals and/or power on the bridge die 305). FIGS. 4A and 4B illustrate examples of IC structures 470A, 470B, which may represent a bridge die. As can be seen in FIGS. 4A, 4B, the IC structures 470A and 470B include a plurality of interconnect layers 454 that include conductive interconnects 327 separated by an ILD material 326. The example in FIG. 4B further includes a plurality of devices 310 in one or more of the interconnect layers.

Referring again to FIGS. 3A and 3B, the interface 313-1 includes a hybrid bonding interface between the IC structures 300A, 300B and the bridge die 305 (e.g., between the die 304-1 and the bridge die 305). The interface 313-2 includes conductive bumps 314 between the IC structures 300A, 300B and the substrate 302 (e.g., between the die 304-2 and the substrate 302). The interface 313-2 includes an insulator material 319 in a plane with the conductive bumps 314 (e.g., in a plane substantially parallel with the substrate 302 and bridge die 305 and substantially parallel with the x-y plane as shown in FIGS. 3A, 3B, where the y-axis is going into and coming out of the page). The interface 313-2 may also be referred to as an interface layer, which include conductive bumps 314. The conductive bumps 314 may be an example of the conductive bumps 114 discussed above. In the example illustrated in FIGS. 3A-3B, a conductive bump is between and coupled with conductive elements in the two bonded IC structures. For example, the conductive bumps shown in FIGS. 3A-3B are either between two conductive pads 329, or between a conductive pad 329 and a conductive via 308. Although only a single die stack (e.g., the IC structures 300A or 300B) is shown between the bridge die 305 and substrate 302, more than one IC structure may be between and bonded with the bridge die 305 and the substrate 302, such as shown in FIGS. 1A and 1B.

The assemblies 350A, 350B also include a plurality of conductive vias 308, each of which may couple with a conductive element of the substrate 302 and/or a conductive element of the bridge die 305. The conductive vias 308 may be formed in an assembly that includes an IC structure 300A, 300B and the bridge die 305, and thus the conductive vias 308 may be considered to be through-assembly conductive vias. In the example shown in FIGS. 3A-3B, the conductive vias 308 have varying lengths, and start and end (e.g., land or terminate) at different points in the assemblies 350A and 350B, where the “start” and “end” of a conductive via may refer to the two ends of a conductive via and may be interchangeable. Some of the conductive vias 308 may start at a side of the first IC die 304-1 bonded with the second die 304-2 (e.g., such as the conductive vias 308-3 and 308-4), at the interface 303A between the dies 304-1 and 304-2 (e.g., such as the conductive vias 308-1 and 308-2). Some of the conductive vias 308 may start at a side of the second die 304-2 that is opposite the side bonded with the first die 304-1 (e.g., the conductive vias 308-5, 308-6, 308-7, 308-9, and 308-10), or at an interface between the second die 304-2 and the substrate 302 (e.g., the conductive via 308-11). Some conductive vias may start at a side of the bridge die 305 coupled with the IC structures 300A or 300B or at the interface between the bridge die 305 and the IC structures 300A or 300B (e.g., the conductive via 308-12). Similarly, some of the conductive vias 308 (e.g., the conductive vias 308-2, 308-4, 308-10, and 308-12) extend into and land on a layer in the bridge die. For example, an end of one or more of the conductive vias 308-2, 308-4, 308-10, and 308-12 is in one of the interconnect layers of the bridge die 305 (e.g., one of the interconnect layers 454 of FIGS. 4A and 4B). Some conductive vias 308 may land at the interface between the bridge die and one of the IC structures 300A or 300B (e.g., the conductive vias 308-1, 308-3, and 308-9). Some conductive vias 308 may land in a layer within the IC structures 300A or 300B (e.g., the conductive vias 308-5, 308-6, 308-7, and 308-8). Thus, the through-assembly conductive vias may start and end in various layers to achieve desired routing and interconnections.

Accordingly, as can be seen in FIGS. 3A and 3B, various ones of the conductive vias 308 may extend through different layers of the assemblies 350A and 350B, and may have different lengths. For example, the conductive vias 308-1, 308-2, 308-3, and 308-4 extend through the first die 304-1 (but not through the second die 304-2), the conductive vias 308-5 and 308-6 extend through the second die 304-2 (but not through the first die 304-1), the conductive vias 308-7 and 308-8 extend through the second die 304-2 and partially through the first die 304-1, and the conductive vias 308-9, 308-10, and 308-11 extend through both the first die 304-1 and the second die 304-2. The conductive via 308-12 extends into the bridge die 305, but not through the dies 304-1, 304-2. Conductive vias which extend entirely through the IC structures 300A or 300B (e.g., the conductive vias 308-9, 308-10, and 308-11) may include portions that are coplanar with the bottom and top layers or faces of the IC structure 300A or 300B. For example, the conductive via 308-10 has a portion or end 337-2 that is in a same plane as a top layer of the die 304-2, and a portion or end 335-2 that is in a same plane as a bottom layer of the die 304-1.

The conductive vias 308 may be formed in the assemblies 350A, 350B after bonding one or more of the dies of the IC structures 300A, 300B with the bridge die 305. Thus, the conductive vias 308 may be formed from the side or face of the dies 304-1, 304-2 opposite the side or face of those dies that is facing and closest to the bridge die 305. Therefore, in the example illustrated in FIGS. 3A and 3B, the conductive vias 308 taper towards the bridge die 305. For example, referring to FIG. 3A, the conductive via 308-2 has a first end 335-1 coupled with a conductive element (e.g., a conductive pad 329), and a second end 337-1 that is opposite the first end 335-1. The first end 335-1 has a first width 359-1 and the second end 337-1 has a second width 359-2 that is larger than the first width 359-1 (where the first width 359-1 and the second width 359-2 are dimensions of the conductive via 308-2 in a plane substantially parallel to the substrate 302 and bridge die 305). In other words, the first end 335-1 of the conductive via 308-2 that is coupled with the conductive element of bridge die 305 is narrower than the second end 337-1 of the conductive via 308-2 that is opposite from the first end 335-1. After attaching the assembly 350A or 350B to a circuit board 301, the first end 335-1 (e.g., the narrower end) of the conductive via 308-2 is closer to the circuit board 301 than the second end 337-1.

Thus, the assemblies 350A and 350B include a plurality of conductive vias that start and end in different planes, some of which extend into the bridge die, and some of which extend through one or more dies of the IC structures 300A, 300B. In one example, an assembly includes a first conductive via (e.g., the conductive via 308-2) including a first bottom end 335-1 in an interconnect structure (e.g., in the bridge die 305), and a first top end 337-1 opposite the first bottom end 335-1. In one such example, the assembly further includes a second conductive via (e.g., the conductive via 308-10) including a second bottom end 335-2 in the interconnect structure and a second top end 337-2 opposite the second bottom end 335-2, where the first top end 337-1 is in a first plane, the second top end 337-2 is in a second plane that is different from the first plane, and the first plane and the second plane are substantially parallel to the interconnect structure (e.g., substantially parallel to the bridge die 305 and parallel to the x-y plane of FIGS. 3A and 3B). Although FIGS. 3A and 3B depict only two dies 304-1 and 304-2 between and bonded with the substrate 302 and bridge die 305, in other examples, the IC structures 300A, 300B may include fewer dies (i.e., a single die) or more than two dies (e.g., three dies, four dies, etc.) between and bonded with the substrate 302 and bridge die 305. In some examples, the conductive interconnects of the substrate 302 and/or bridge die 305 couple with the conductive vias 308 though the dies 304-1, 304-2 and/or with conductive vias through other dies or die stacks bonded with bridge die 305 or the substrate 302.

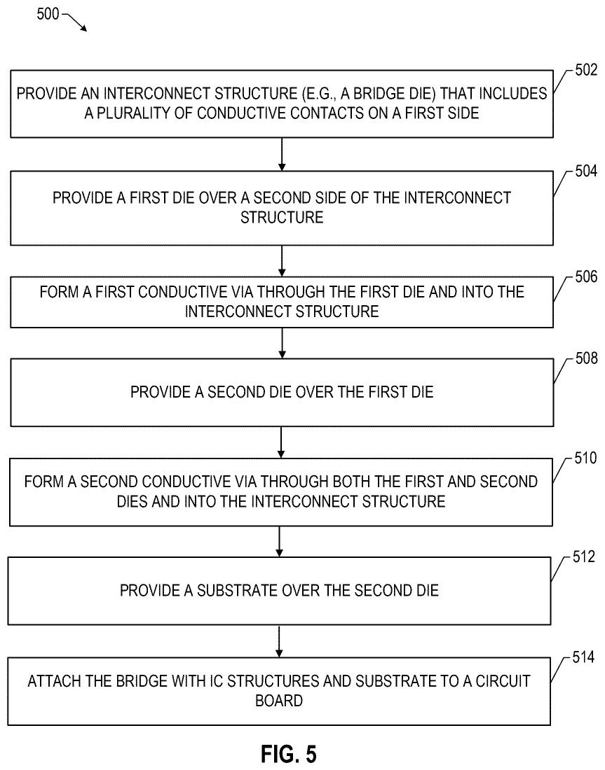

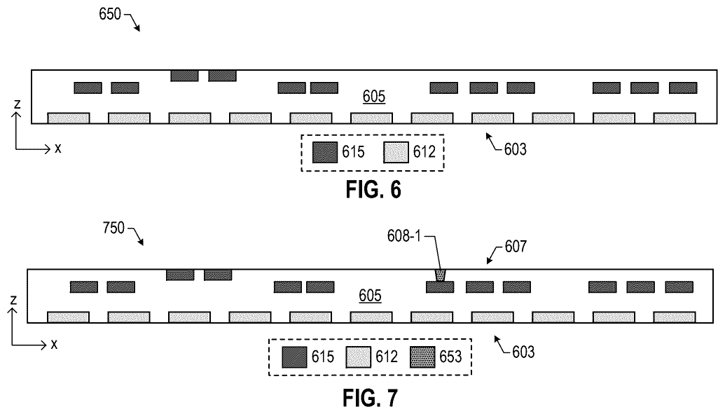

FIG. 5 is a flow diagram of an example method 500 for fabricating a microelectronic assembly including through-assembly conductive vias of varying depth. FIGS. 6-9, 10A, 10B, and 11-13 provide different views at various stages in the fabrication of an example assembly according to the method of FIG. 5, in accordance with some embodiments. Although the operations of the method of FIG. 5 are illustrated once each and in a particular order, the operations may be performed in any suitable order and repeated as desired. For example, one or more operations may be performed in parallel to fabricate multiple microelectronic assemblies with through-assembly conductive vias of varying lengths substantially simultaneously. In another example, the operations may be performed in a different order to reflect the structure of a microelectronic assembly in which through-assembly conductive vias of varying depth will be implemented.

In addition, the example fabricating method of FIG. 5 may include other operations not specifically shown in FIG. 5, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 5 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 5, the method 500 begins with a process 502 of providing an interconnect structure that includes a plurality of conductive contacts on a first side. The assembly 650 of FIG. 6 is an example resulting assembly of the process 502. The assembly 650 includes an interconnect structure 605, which may be an example of the bridge die 105, discussed above. The interconnect structure includes a plurality of conductive contacts 612 on a first side 603. The conductive contacts 612 on the first side 603 are for coupling with corresponding contacts on a circuit board, and may include, e.g., conductive pads, or other suitable conductive contacts. The interconnect structure 605 may include a plurality of interconnect layers with conductive interconnects, such as shown in the IC structures 470A and 470B of FIGS. 4A and 4B. The interconnect structure 605 includes conductive elements 615 for coupling with through-assembly conductive vias. The conductive elements may include conductive pads, conductive lines, or other suitable conductive elements.

The method may involve forming a conductive via in the interconnect structure prior to providing IC structures over the interconnect structure. The assembly 750 of FIG. 7 is an example resulting assembly of the process of forming a conductive via in the interconnect structure prior to providing IC structures over the interconnect structure. The assembly 750 includes a conductive via 608-1 extending from the second side 607 of the interconnect structure 605 and into the interconnect structure 605. Forming the conductive via in the interconnect structure 605 may involve first forming an opening in the interconnect structure 605 and filling the opening with a conductive material 653. Forming an opening may involve any suitable masking and etching techniques that enable etching through the material(s) of the interconnect structure 605. Any suitable etching technique, e.g., a dry etch, such as e.g., radio frequency (RF) reactive ion etch (RIE) or inductively coupled plasma (ICP) RIE may be used to form a via opening in the interconnect structure. The electrically conductive material 653 may include any suitable electrically conductive material, such as any of those described above, and may be deposited using a technique such as atomic layer deposition (ALD), chemical vapor deposition (CVD), plasma enhanced CVD (PECVD), or/and physical vapor deposition (PVD) processes such as sputter. Although not shown in FIG. 6, a liner may be provided in the via opening prior to filling the opening with the conductive material 653. The conductive via 608-1 may land on, and be coupled with, a conductive element 615 of the interconnect structure 605. In some examples, prior to forming the conductive via 608-1, an interface layer with conductive bumps may be provided over the interconnect structure 605 (not shown in FIG. 7). In one such example, the conductive via 608-1 may also extend through such an interface layer (e.g., between adjacent conductive bumps).

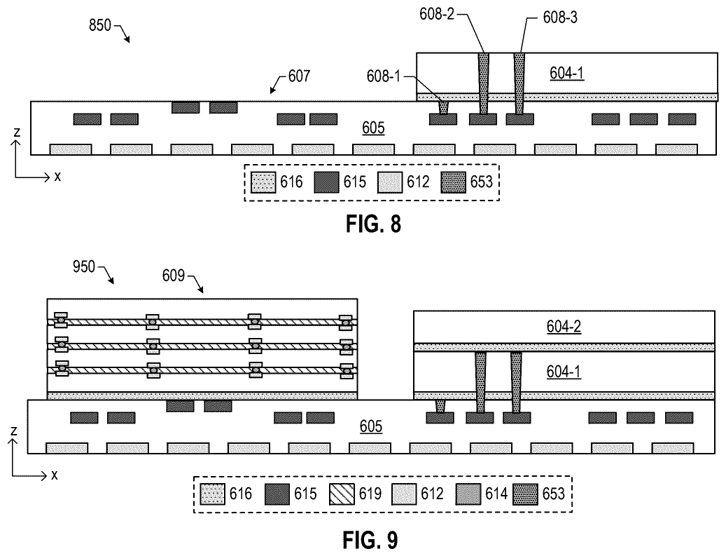

Referring again to FIG. 5, the method 500 continues with a process 504 of providing a first die over a second side of the interconnect structure and a process 506 of forming a first conductive via through the first die and into the interconnect structure. The assembly 850 of FIG. 8 is an example resulting assembly of the processes 504 and 506. The assembly 850 includes a first die 604-1 over and bonded with the second side 607 of the interconnect structure 605. In the example illustrated in FIG. 8, the die 604-1 is hybrid bonded with the interconnect structure 605, as indicated by the hybrid bonding interface 616. In other examples, the first die 604-1 may be coupled with the interconnect structure 605 via any other suitable bonding technique. The assembly also includes conductive vias 608-2 and 608-3 through the first die 604-1 and extending into the interconnect structure 605. Forming the conductive vias 608-2 and 608-3 may involve a process similar to the process discussed above with the formation of the conductive via 608-1, e.g., etching openings and filling the openings with the conductive material 653.

The method 500 continues with a process 508 of providing a second die over the first die. The assembly 950 of FIG. 9 is an example resulting assembly of the process 508. The assembly 950 includes a second die 604-2 over the first die 604-1. In the example illustrated in FIG. 9, the second die 604-2 is hybrid bonded with the first die 604-1; however, any suitable bonding technique may be used to bond the second die 604-2 with the first die 604-1. The second die 604-2 may be the same type of die (e.g., two instances of substantially identical dies) or different types of dies, and may have the same or different dimensions. In various examples, one or more other IC structures may be provided over the interconnect structure 605 before or after forming the conductive vias 608-2, 608-3. For example, the assembly 950 includes a die stack 609 adjacent to the dies 604-1, 604-2. The die stack 609 illustrated in FIG. 9 includes a plurality of dies stacked over one another and bonded together with conductive bumps 614, and may include an insulator material 619 in a plane with the conductive bumps 614. However, other IC structures (e.g., a single die, a die stack having a different number of dies and/or different interfaces, etc.) may be provided over the interconnect structure. Additional and/or different IC structures may be provided over the interconnect structure 605, such as shown in the example assemblies 150A and 150B of FIGS. 1A and 1B.

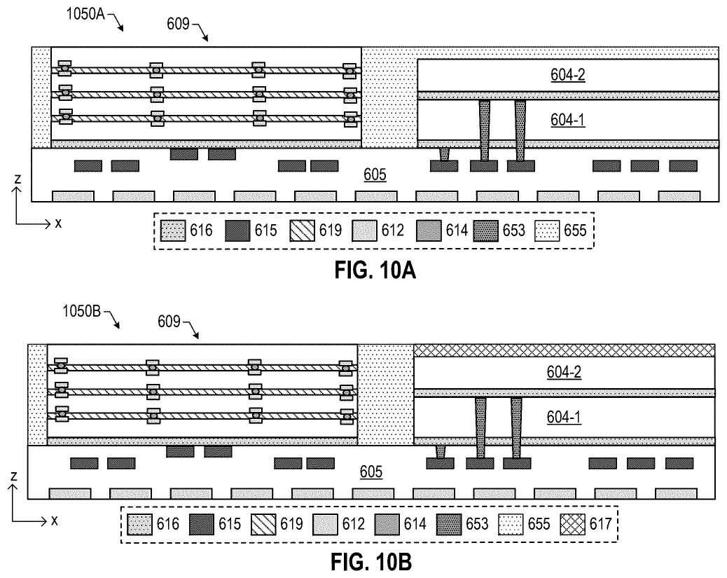

The method may also involve providing an insulator material around and between adjacent IC structures over the interconnect structure 605, and may also involve providing an insulator material and/or dummy die over one or more IC structures in order to compensate for height differences amongst IC structures. The assembly 1050A of FIG. 10A is an example resulting assembly of the process of providing an insulator material over a shorter one of the IC structures bonded with the interconnect structure. The assembly 1050A includes an insulator material 655 between the die stack 609 and the dies 604-1, 604-2, as well as over the die 604-2. The insulator material 655 may be an example of the insulator material 215, discussed above. The assembly 1050B of FIG. 10B is an example resulting assembly of the process of providing a dummy die over a shorter one of the IC structures bonded with the interconnect structure. The assembly 1050B includes the insulator material 655 between the die stack 609 and the dies 604-1, 604-2, and a dummy die 617 over the die 604-2. The dummy die 617 may be an example of the dummy die 217, discussed above. Thus, the resulting height or thickness of the die stack 609 is substantially the same as the dies 604-1 and 604-2 with the insulator material 655 or dummy die 617. The subsequent figures depicting assemblies during various stages of performance of the method 500 are based on the assembly 1050A; however, in other examples, one or more dummy dies may be used in addition to, or alternatively to, the insulator material 655. Furthermore, in other examples, a dummy die and/or insulator material may be absent over one or more coplanar IC structures over the interconnect structure 605 (e.g., in an example in which coplanar IC structures bonded with the interconnect structure 605 have substantially the same height, or in an example in which a substrate is not provided over the IC structures).

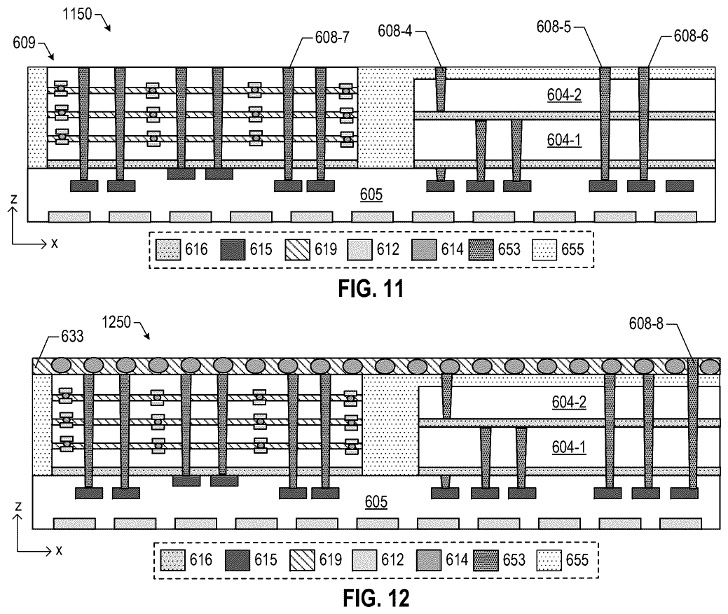

The method 500 continues with a process 510 of forming a second conductive via through both the first and second dies and into the interconnect structure. The assembly 1150 of FIG. 11 is an example resulting assembly of the process 510. The assembly 1150 includes the conductive vias 608-5 and 608-6, which extend through both the dies 604-1 and 604-2, and which extend into the interconnect structure 605. The assembly also includes the conductive via 608-4, which extends through the second die 604-2, but not through the first die 604-1. Additionally, the assembly 1150 includes conductive vias 608-7 through the die stack 609 (only one conductive via 608-7 through the die stack 609 is labeled in order to not clutter the drawing). Forming the conductive vias 608-4, 608-5, 608-6, and 608-7 may involve etch and deposition techniques such as those discussed above.

The method may involve providing an interface layer over the second die and the die stack to facilitate bonding a substrate with the assembly 1250. The assembly 1250 of FIG. 12 is an example resulting assembly of the process of providing an interface layer over the second die and the die stack. The assembly 1250 includes an interface 633 (e.g., interface layer), which includes a plurality of conductive bumps and the insulator material 619 in a plane with the conductive bumps. In one such example, a further conductive via 608-8 may be formed through the interface 633. In other examples, a substrate may be bonded with the assembly 1250 without conductive bumps (e.g., via hybrid bonding or other suitable technique), or a substrate may be omitted from the final assembly.

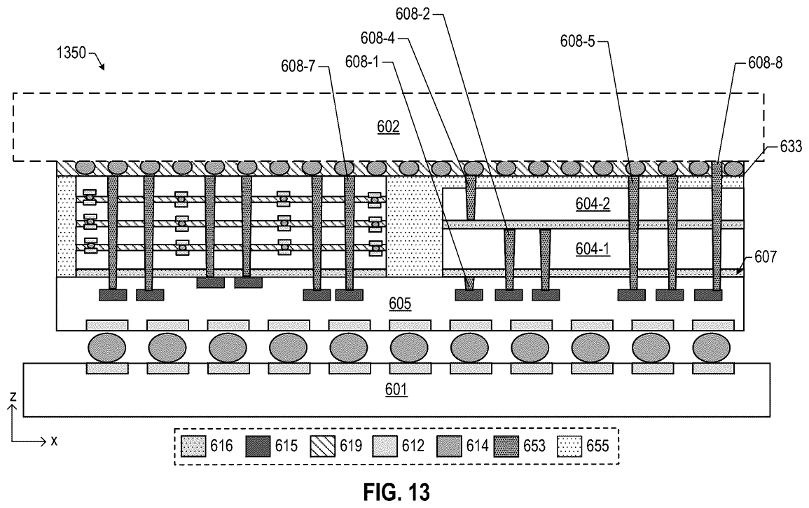

The method 500 continues with a process 512 of providing a substrate over the second die and a process 514 of attaching the bridge with IC structures and substrate to a circuit board. The assembly 1350 of FIG. 13 is an example resulting assembly of the processes 512 and 514. The assembly 1350 includes a circuit board 601 to which the bridge die 605 has been attached via a plurality of conductive bumps. In other examples, the bridge die 605 may be attached to the circuit board via other suitable techniques. The assembly 1350 also includes a substrate 602 over and bonded with the die stack 609 and the die 604-2. In other examples, the substrate 602 may be absent from the final assembly.

Thus, FIG. 5 illustrates a method 500 for fabricating microelectronic assemblies including through-assembly conductive vias of varying depth. Performing the method 500 may result in several features in the final assembly that are characteristic of the use of the method 500. For example, one such feature characteristic of the use of the method 500 is illustrated in the assembly shown in FIG. 13, in which the assembly 1350 includes conductive vias of varying depth. For example, the conductive via 608-1 extends into the interconnect structure 605 but not through the dies 604-1, 604-2 (e.g., its top end or portion is coplanar with the second side 607 of the interconnect structure 605 and/or in a plane between the interconnect structure 605 and the die 604-1), the conductive via 608-2 extends through one die 604-1 and into the interconnect structure 605, the conductive via 608-5 extends through two dies 604-1, 604-2 and into the interconnect structure 605, the conductive via 608-7 extends through multiple dies in the die stack 609 and into the interconnect structure, and the conductive via 608-8 extends through the dies 604-1, 604-2 and through the interface 633 with the substrate 602. Additionally, the conductive vias 608-1, 608-2, 608-3, 608-4, 608-5, 608-6, 608-7, and 608-8 taper in a direction towards the interconnect structure. In some examples, one or more of the conductive vias 608-1, 608-2, 608-3, 608-4, 608-5, 608-6, 608-7, and 608-8 may extend through one or more interfaces with conductive bumps. Different ones of the conductive vias 608-1, 608-2, 608-3, 608-4, 608-5, 608-6, 608-7, and 608-8 may be coupled together with conductive interconnects in the interconnect die and/or in the substrate 602. Accordingly, through-assembly conductive vias with varying lengths can enable higher performance inter-die connectivity and increased flexibility in terms of multi-fabrication processing and interconnect routing.

IC devices, structures, and assemblies including through-assembly conductive vias of varying depth as described herein (e.g., as described with reference to FIGS. 1A-1E, 2, 3A-3B, 4A-4B, 5, 6-9, 10A, 10B, and 11-13) may be used to implement any suitable components. For example, in various embodiments, IC devices described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), a system including one or more of the aforementioned devices, etc.

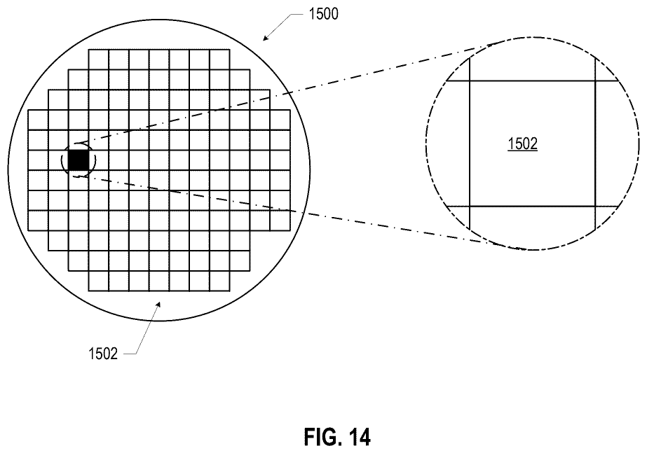

The devices, structures, and assemblies disclosed herein, e.g., the assemblies 150A, 150B, 160E, 350A, 350B, and 1350, or any variations thereof, may be included in any suitable electronic component. FIGS. 14-17 illustrate various examples of apparatuses that may include any of the IC structures or assemblies disclosed herein.

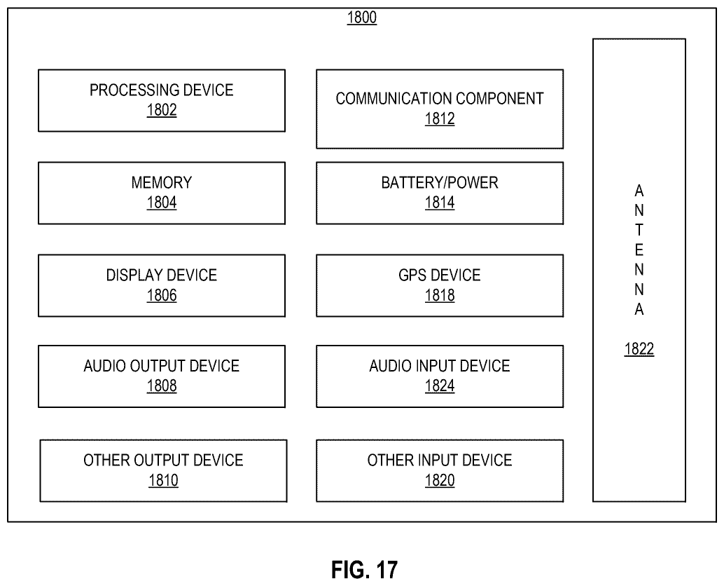

FIG. 14 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the structures and/or dies, or any variations thereof described herein, or any combination of such IC structures), one or more transistors and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 17) or other logic that is configured to store information in the memory devices or execute instructions stored in the memory array.

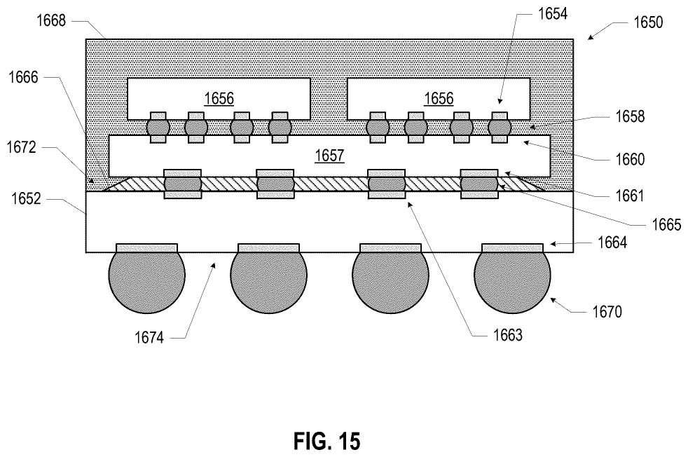

FIG. 15 is a side, cross-sectional view of an example IC package 1650 that may include one or more IC structures in accordance with any of the embodiments disclosed herein (e.g., any of the assemblies 150A, 150B, 160E, 350A, 350B, and 1350, or any variations thereof described herein, or any combination). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 15 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 15 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 15 are solder balls (e.g., for a BGA arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 14.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 15 is a flip chip package, other package architectures may be used. For example, the IC package 1650 may be a BGA package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 15, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

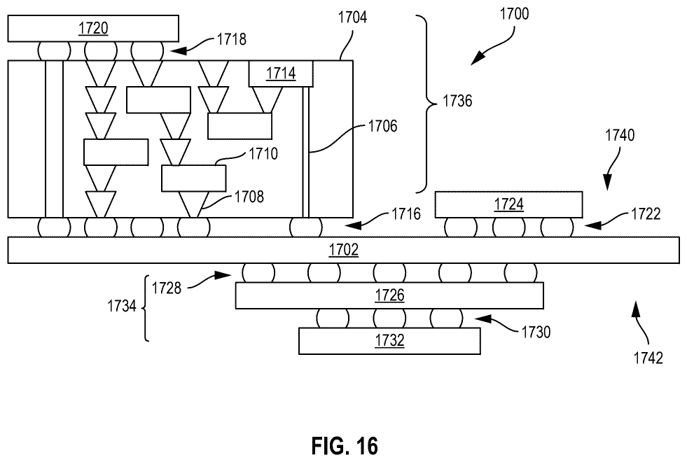

FIG. 16 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 15 (e.g., may include one or more of assemblies 150A, 150B, 160E, 350A, 350B, and 1350, or any variations thereof described herein, or any combination of such structures).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 16 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 16), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 16, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 14), an IC device, an assembly (e.g., one or more of assemblies 150A, 150B, 160E, 350A, 350B, and 1350, or any variations thereof described herein, or any combination of such structures), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 16, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 16 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 17 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 17 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 17, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides a microelectronic assembly, including an interconnect structure (e.g., a bridge die) including conductive contacts on a first side; an IC structure bonded with a second side of the interconnect structure that is opposite the first side, where the IC structure includes at least one die; a first conductive via including a first bottom end in the interconnect structure and a first top end opposite the first bottom end; and a second conductive via including a second bottom end in the interconnect structure and a second top end opposite the second bottom end, where: the first top end is in a first plane, the second top end is in a second plane that is different from the first plane, and the first plane and the second plane are substantially parallel to the interconnect structure.

Example 2 provides the microelectronic assembly of example 1, where: the first conductive via extends through the at least one die, and the second plane is between the second side of the interconnect structure and the IC structure (e.g., the first conductive via extends through the at least one die, and the second conductive via extends between a layer of the interconnect die and either the second side of the interconnect die or an interface between the interconnect die and the IC structure).

Example 3 provides the microelectronic assembly of example 1 or 2, where: the at least one die is a first die, the IC structure includes a second die stacked over and bonded with the first die, the first conductive via extends through the first die and the first plane is between the second side of the interconnect structure and the second die, and the second conductive via extends through the first die and the second die.

Example 4 provides the microelectronic assembly of any one of examples 1-3, where: the first bottom end has a first width, where the first width is a dimension of the first bottom end in a third plane substantially parallel with the interconnect structure, the first top end has a second width, where the second width is a dimension of the first bottom end in a fourth plane substantially parallel with the interconnect structure, and the second width is greater than the first width.

Example 5 provides the microelectronic assembly of any one of examples 1-4, where the IC structure is a first IC structure, and where the microelectronic assembly further includes a second IC structure coplanar with the first IC structure; and a third conductive via including a third bottom end in the interconnect structure and a third top end opposite the third bottom end, where: the third top end is in a third plane that is different from one or more of the first plane and the second plane, and the third plane is substantially parallel to the interconnect structure.

Example 6 provides the microelectronic assembly of example 5, where: the first conductive via is coupled with the third conductive via with one or more conductive interconnects of the interconnect structure.

Example 7 provides the microelectronic assembly of example 5, further including a substrate over and bonded with the first IC structure and the second IC structure.

Example 8 provides the microelectronic assembly of example 7, where: the first conductive via is coupled with the third conductive via with one or more conductive interconnects of the substrate.

Example 9 provides the microelectronic assembly of example 7 or 8, further including a plurality of conductive bumps between the substrate and the first IC structure, where the first conductive via is coupled with one of the plurality of conductive bumps.

Example 10 provides the microelectronic assembly of any one of examples 7 or 8, further including a plurality of conductive bumps between the substrate and the first IC structure, where the first conductive via includes a portion that is coplanar with the plurality of conductive bumps.

Example 11 provides the microelectronic assembly of any one of examples 5-10, further including an insulator material between the first IC structure and the second IC structure and over the second IC structure in a fourth plane with the first IC structure, where the fourth plane is substantially parallel to the interconnect structure.

Example 12 provides the microelectronic assembly of any one of examples 5-10, further including a dummy die over the second IC structure in a fourth plane with the first IC structure, where the fourth plane is substantially parallel to the interconnect structure.

Example 13 provides the microelectronic assembly of any one of examples 5-12, further including a plurality of conductive bumps between the first IC structure and the interconnect structure, where a portion of the first conductive via is in a fourth plane with the plurality of conductive bumps.

Example 14 provides the microelectronic assembly of any one of examples 5-13, further including a circuit board under and bonded with the interconnect structure; and a plurality of conductive bumps between the circuit board and the interconnect structure, where one of the plurality of conductive bumps is coupled with one of the conductive contacts.

Example 15 provides a microelectronic assembly including an interconnect structure including a plurality of conductive contacts on a first side and a plurality of interconnect layers; a substrate over the interconnect structure; a plurality of coplanar IC structures between and coupled with the interconnect structure and the substrate, where the plurality of IC structures includes a first IC structure including one or more first dies and a second IC structure including one or more second dies; a first conductive via through at least one of the one or more first dies and extending into the interconnect structure; and a second conductive via through at least one of the one or more second dies and extending into the interconnect structure, where: the first conductive via has a first length, where the first length is a dimension of the first conductive via in a first plane orthogonal to the substrate, the second conductive via has a second length, where the second length is a dimension of the second conductive via in a second plane orthogonal to the substrate, and the first length is different from the second length.

Example 16 provides the microelectronic assembly of example 15, where the one or more first dies includes at least two dies, and where the microelectronic assembly further includes a third conductive via through the at least two dies of the first IC structure and extending into the interconnect structure, where the first conductive via and the third conductive via extend through a different number of dies of the first IC structure.

Example 17 provides the microelectronic assembly of example 15 or 16, where: the first conductive via and the second conductive via taper in a direction from the substrate towards the interconnect structure.

Example 18 provides the microelectronic assembly of any one of examples 15-17, where the interconnect structure is a first interconnect structure, and where the microelectronic assembly further includes a second interconnect structure coplanar with the first interconnect structure; a further IC structure between and bonded with the second interconnect structure and the substrate, where the further IC structure includes one or more further dies; and a further conductive via through at least one of the one or more further dies and extending into the second interconnect structure.

Example 19 provides the microelectronic assembly according to any one of examples 1-18, where the microelectronic assembly includes or is a part of a central processing unit.

Example 20 provides the microelectronic assembly according to any one of examples 1-20, where the microelectronic assembly includes or is a part of a memory device.

Example 21 provides the microelectronic assembly according to any one of examples 1-20, where the microelectronic assembly includes or is a part of a logic circuit.

Example 22 provides the microelectronic assembly according to any one of examples 1-21, where the microelectronic assembly includes or is a part of input/output circuitry.

Example 23 provides the microelectronic assembly according to any one of examples 1-22, where the microelectronic assembly includes or is a part of a field programmable gate array transceiver.

Example 24 provides the microelectronic assembly according to any one of examples 1-23, where the microelectronic assembly includes or is a part of a field programmable gate array logic.

Example 25 provides the microelectronic assembly according to any one of examples 1-24, where the microelectronic assembly includes or is a part of a power delivery circuitry.

Example 26 provides an IC package that includes a microelectronic assembly according to any one of examples 1-18.

Example 27 provides the IC package according to example 26, further including a further IC component coupled to the microelectronic assembly.

Example 28 provides the IC package according to example 27, where the further IC component includes a package substrate.

Example 29 provides the IC package according to example 27, where the further IC component includes an interposer.

Example 30 provides the IC package according to example 27, where the further IC component includes a further assembly or die.

Example 31 provides a computing device that includes a carrier substrate and an assembly coupled to the carrier substrate, where the assembly is an assembly according to any one of examples 1-18, or the assembly is included in the IC package according to any one of examples 26-30.

Example 32 provides the computing device according to example 31, where the computing device is a wearable or handheld computing device.

Example 33 provides the computing device according to examples 31 or 32, where the computing device further includes one or more communication chips.

Example 34 provides the computing device according to any one of examples 31-33, where the computing device further includes an antenna.

Example 35 provides the computing device according to any one of examples 31-34, where the carrier substrate is a motherboard.

Example 36 provides a method of fabricating a microelectronic assembly, the method including providing an interconnect structure including a plurality of conductive pads on a first side and a plurality of interconnect layers; providing a first die over a second side of the interconnect structure; forming a first conductive via through the first die and into the interconnect structure; providing a second die over the first die; and forming a second conductive via through the first die and the second die and into the interconnect structure.

Example 37 provides the method of example 36, further including prior to providing the first die, forming a third conductive via in the interconnect structure.

Example 38 provides the method of example 37, further including prior to providing the first die, providing an interface layer including conductive bumps over the interconnect structure, where: forming the third conductive via includes forming the third conductive via through the interface layer (e.g., between adjacent conductive bumps).

Example 39 provides the method of any one of examples 36-38, further including providing a die stack adjacent to the first die; and forming a third conductive via through the die stack and into the interconnect structure.

Example 40 provides the method of example 39, further including providing an insulator material around and between the first die and the die stack.

Example 41 provides the method of example 40, further including providing the insulator material over a shorter one of: the second die and the die stack.

Example 42 provides the method of example 39, further including providing a dummy die over a shorter one of: the first die and the die stack.

Example 43 provides the method of any one of examples 39-42, further including providing a substrate over the second die and the die stack.

Example 44 provides the method of example 43, further including prior to providing the substrate, providing an interface layer over the second die and the die stack; and forming a fourth conductive via through the interface layer.

Example 45 provides the method of any one of examples 36-44, where: providing the first die includes bonding the first die to the interconnect structure with hybrid bonding.

Example 46 provides the method of any one of examples 36-44, where: providing the first die includes bonding the first die to the interconnect structure with conductive bumps.

Example 47 provides the method of any one of examples 36-46, further including attaching the first side of the bridge die to a circuit board.

Example 48 provides the method according to any one of examples 36-47, where the microelectronic assembly is a microelectronic assembly according to any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A microelectronic assembly, comprising:
an interconnect structure comprising conductive contacts on a first side;
an integrated circuit (IC) structure bonded with a second side of the interconnect structure that is opposite the first side, wherein the IC structure comprises at least one die;
a first conductive via comprising a first bottom end in the interconnect structure and a first top end opposite the first bottom end; and
a second conductive via comprising a second bottom end in the interconnect structure and a second top end opposite the second bottom end, wherein:
the first top end is in a first plane,
the second top end is in a second plane that is different from the first plane, and
the first plane and the second plane are substantially parallel to the interconnect structure.

2. The microelectronic assembly of claim 1, wherein:
the first conductive via extends through the at least one die, and
the second plane is between the second side of the interconnect structure and the IC structure.

3. The microelectronic assembly of claim 1, wherein:
the at least one die is a first die,
the IC structure comprises a second die stacked over and bonded with the first die,
the first conductive via extends through the first die and the first plane is between the second side of the interconnect structure and the second die, and
the second conductive via extends through the first die and the second die.

4. The microelectronic assembly of claim 1, wherein:
the first bottom end has a first width, wherein the first width is a dimension of the first bottom end in a third plane substantially parallel with the interconnect structure,
the first top end has a second width, wherein the second width is a dimension of the first bottom end in a fourth plane substantially parallel with the interconnect structure, and
the second width is greater than the first width.

5. The microelectronic assembly of claim 1, wherein the IC structure is a first IC structure, and wherein the microelectronic assembly further comprises:
a second IC structure coplanar with the first IC structure; and
a third conductive via comprising a third bottom end in the interconnect structure and a third top end opposite the third bottom end, wherein:
the third top end is in a third plane that is different from one or more of the first plane and the second plane, and
the third plane is substantially parallel to the interconnect structure.

6. The microelectronic assembly of claim 5, wherein:
the first conductive via is coupled with the third conductive via with one or more conductive interconnects of the interconnect structure.

7. The microelectronic assembly of claim 5, further comprising:
a substrate over and bonded with the first IC structure and the second IC structure.

8. The microelectronic assembly of claim 7, wherein:
the first conductive via is coupled with the third conductive via with one or more conductive interconnects of the substrate.

9. The microelectronic assembly of claim 7, further comprising:
a plurality of conductive bumps between the substrate and the first IC structure, wherein the first conductive via is coupled with one of the plurality of conductive bumps.

10. The microelectronic assembly of claim 7, further comprising:
a plurality of conductive bumps between the substrate and the first IC structure, wherein the first conductive via comprises a portion that is coplanar with the plurality of conductive bumps.

11. The microelectronic assembly of claim 5, further comprising:
an insulator material between the first IC structure and the second IC structure and over the second IC structure in a fourth plane with the first IC structure, wherein the fourth plane is substantially parallel to the interconnect structure.

12. The microelectronic assembly of claim 5, further comprising:
a dummy die over the second IC structure in a fourth plane with the first IC structure, wherein the fourth plane is substantially parallel to the interconnect structure.

13. The microelectronic assembly of claim 5, further comprising:
a plurality of conductive bumps between the first IC structure and the interconnect structure, wherein a portion of the first conductive via is in a fourth plane with the plurality of conductive bumps.

14. The microelectronic assembly of claim 5, further comprising:
a circuit board under and bonded with the interconnect structure; and
a plurality of conductive bumps between the circuit board and the interconnect structure, wherein one of the plurality of conductive bumps is coupled with one of the conductive contacts.

15. A microelectronic assembly comprising:
an interconnect structure comprising a plurality of conductive contacts on a first side and a plurality of interconnect layers;
a substrate over the interconnect structure;
a plurality of coplanar integrated circuit (IC) structures between and coupled with the interconnect structure and the substrate, wherein the plurality of IC structures comprises a first IC structure comprising one or more first dies and a second IC structure comprising one or more second dies;
a first conductive via through at least one of the one or more first dies and extending into the interconnect structure; and
a second conductive via through at least one of the one or more second dies and extending into the interconnect structure, wherein:
the first conductive via has a first length, wherein the first length is a dimension of the first conductive via in a first plane orthogonal to the substrate,
the second conductive via has a second length, wherein the second length is a dimension of the second conductive via in a second plane orthogonal to the substrate, and
the first length is different from the second length.

16. The microelectronic assembly of claim 15, wherein the one or more first dies comprises at least two dies, and wherein the microelectronic assembly further comprises:
a third conductive via through the at least two dies of the first IC structure and extending into the interconnect structure, wherein the first conductive via and the third conductive via extend through a different number of dies of the first IC structure.

17. The microelectronic assembly of claim 15, wherein:
the first conductive via and the second conductive via taper in a direction from the substrate towards the interconnect structure.

18. The microelectronic assembly of claim 15, wherein the interconnect structure is a first interconnect structure, and wherein the microelectronic assembly further comprises:
a second interconnect structure coplanar with the first interconnect structure;
a further IC structure between and bonded with the second interconnect structure and the substrate, wherein the further IC structure comprises one or more further dies; and
a further conductive via through at least one of the one or more further dies and extending into the second interconnect structure.

19. A method of fabricating a microelectronic assembly, the method comprising:
providing an interconnect structure comprising a plurality of conductive pads on a first side and a plurality of interconnect layers;
providing a first die over a second side of the interconnect structure;
forming a first conductive via through the first die and into the interconnect structure;
providing a second die over the first die; and
forming a second conductive via through the first die and the second die and into the interconnect structure.

20. The method of claim 19, further comprising:
prior to providing the first die, forming a third conductive via in the interconnect structure.
